(19) United States
(12) Patent Application Publication
(10) Pub. No.: US 2023/0140283 A1
(43) Pub. Date: May 4, 2023

(54) SEMICONDUCTOR SUBSTRATE PROCESSING APPARATUS

(71) Applicant: ASM IP Holding B.V., Almere (NL)

(72) Inventors: Theodorus G.M. Oosterlaken, Oudewater (NL); Dieter Pierreux, Pepingen (BE)

(21) Appl. No.: 18/051,803

(22) Filed: Nov. 1, 2022

Related U.S. Application Data
(60) Provisional application No. 63/274,666, filed on Nov. 2, 2021.

(51) Int. Cl. H01L 21/673; C23C 16/458

(52) U.S. Cl. CPC H01L 21/6732; C23C 16/4581

(57) ABSTRACT

A semiconductor substrate processing apparatus, comprising a processing chamber, a wafer boat and a plurality of wafer supports. The wafer boat is configured to accommodate a plurality of wafers and is receivable in the processing chamber for depositing a layer on each wafer. The wafer boat comprises at least two wafer boat posts, wherein each wafer boat post comprises a plurality of slots. Each wafer support comprises a support area configured to support at least a circumferential edge of a wafer, and a flange circumferentially surrounding the support area. The flange is receivable in and supported by the slots and has a width to create a distance between the circumferential edge of the wafer and the wafer boat posts. The distance is such that the wafer boat posts do substantially not influence a layer thickness of the layer which is deposited on the wafer during processing of the wafer.

### FIELD OF THE DISCLOSURE

The present disclosure generally relates to a semiconductor substrate processing apparatus.

### BACKGROUND

In a semiconductor substrate processing apparatus, such as a vertical batch furnace, atomic layer deposition (ALD) apparatus, and the like, a wafer may be treated in a process chamber by depositing a layer of deposition material on said wafer. The wafer may be loaded in a wafer boat which may accommodate a plurality of spaced apart wafers. The wafer boat with loaded wafers may be placed in the process chamber for treatment. Uniform depositing of the material on the wafer in the wafer boat may be important for obtaining high quality wafers. A known problem may be the accumulation of deposited material near an outer edge of the wafer, i.e. in an outer edge zone of the wafer, making the layer in said outer edge zone thicker than elsewhere on the wafer. This edge effect may decrease the quality of the wafer and may reduce the effective area of the wafer. Also posts of the wafer boat containing slots by which the wafers are supported may disturb the deposition process so that the layer thickness which is deposited on the wafer adjacent the posts may be different from the layer thickness at parts of the wafer which are more remote from the posts.

It is known to put a shielding ring in a slot in the wafer boat above the wafer, wherein the shielding ring shields the outer edge zone of the wafer against superfluous deposition.

### SUMMARY

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

It may be realized that in the known substrate processing apparatus using the shielding rings, deposition material is still accumulated near and deposited on the outer edge zone of the wafer.

It may be an object to provide a semiconductor processing apparatus in which the accumulation of deposition material on the outer edge zone of the wafer is less than in the known semiconductor processing apparatus.

To that end, there may be provided a semiconductor substrate processing apparatus. The semiconductor substrate processing apparatus may comprise a processing chamber, a wafer boat, and a plurality of wafer supports. The processing chamber may be configured for batch processing a plurality of wafers. The processing may include depositing a layer on each wafer of the plurality of wafers. The wafer boat may be configured to accommodate the plurality of wafers and be receivable in the processing chamber. The wafer boat may comprise at least two wafer boat posts. Each wafer boat post may comprise a plurality of slots. Each wafer support of the plurality of wafer supports may comprise a support area and a flange. The support area may be configured to support at least a circumferential edge of a wafer of the plurality of wafers. The flange may circumferentially surround the support area. The flange may be receivable in and supported by the slots. The flange may have a width to create a distance between the circumferential edge of the wafer of the plurality of wafers and the wafer boat posts of the wafer boat. The distance may be such that the wafer boat posts do substantially not influence a layer thickness of the layer which is deposited on the wafer during processing of the wafer.

There may also be provided another semiconductor substrate processing apparatus. The semiconductor substrate processing apparatus may comprise a processing chamber, a wafer boat, and a shield ring. The processing chamber may be configured for batch processing a plurality of wafers. The processing may include depositing a layer on each wafer of the plurality of wafers. The wafer boat may be configured to accommodate the plurality of wafers and be receivable in the processing chamber. The wafer boat may comprise at least two wafer boat posts. Each wafer boat post may comprise a plurality of slots. The shield ring may be configured to be supported in the slots of the wafer boat posts above an associated wafer. The shield ring may shield a circumferential outer edge zone at an upper surface of the associated wafer. The circumferential outer edge zone may be ring-shaped, have a radial width and extend circumferentially along a circumferential edge of the wafer. A surface part of the shield ring may define a nominal surface area which is a surface area of the surface part if it were flat. The surface part has a surface structure which may provide an enhanced surface area. An enhanced surface area ratio may be defined by the enhanced surface area of the surface part having the surface structure divided by the nominal surface area. The enhanced surface area ratio is higher than 1.5.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

Various embodiments are claimed in the dependent claims, which will be further elucidated with reference to an example shown in the figures. The embodiments may be combined or may be applied separate from each other.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE FIGURES

While the specification concludes with claims particularly pointing out and distinctly claiming what are regarded as embodiments of the invention, the advantages of embodiments of the disclosure may be more readily ascertained from the description of certain examples of the embodiments of the disclosure when read in conjunction with the accompanying drawings, in which:

FIG. 1 shows an example of a semiconductor substrate processing apparatus according to the description;

FIG. 2 shows a schematic and exaggerated representation of a thickness of a deposited layer on a wafer, in particular at a cross-section through the wafer which contains two edge zone areas of the wafer which have been remote from the posts of the wafer boat in which the wafer was placed when being processed, wherein no shield rings were present in a wafer boat during processing;

FIG. 3a shows a schematic cross section view of an example of a known wafer boat with wafers placed therein, in particular at a cross-section through the wafer posts of the wafer boat;

FIG. 3b shows a schematic and exaggerated representation of a thickness of a deposited layer on the wafers in the wafer boat as depicted in FIG. 3a along the shown cross section through the wafer boat posts when no shield rings are used during processing;

FIG. 4 shows a schematic cross section view of an example according to the description of a wafer boat with wafers and wafer supports placed therein;

FIG. 5 shows a schematic cross section view of an example according to the description of a wafer boat with wafer supports and wafers placed therein;

FIG. 6 shows a schematic cross section view of an example according to the description of a wafer boat with wafers and shield rings placed therein;

FIG. 7 shows a schematic representation of a nominal and an enhanced surface area of a surface part with an enhanced surface area of a shield ring according to the description; and

FIG. 8 shows a cross-sectional detail of the right-hand part of a wafer support as shown in FIG. 5.

### DETAILED DESCRIPTION

In this application similar or corresponding features are denoted by similar or corresponding reference signs. The description of the various embodiments is not limited to the examples shown in the figures and the reference numbers used in the detailed description and the claims are not intended to limit the description of the embodiments, but are included to elucidate the embodiments.

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below. The illustrations presented herein are not meant to be actual views of any particular material, structure, or device, but are merely idealized representations that are used to describe embodiments of the disclosure.

As used herein, the term “wafer” may refer to any underlying material or materials that may be used, or upon which, a device, a circuit, or a film may be formed.

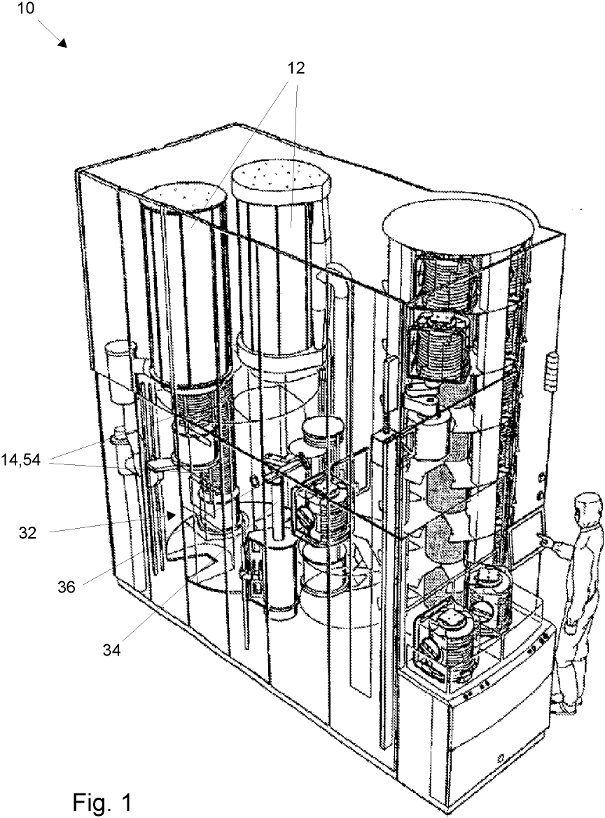

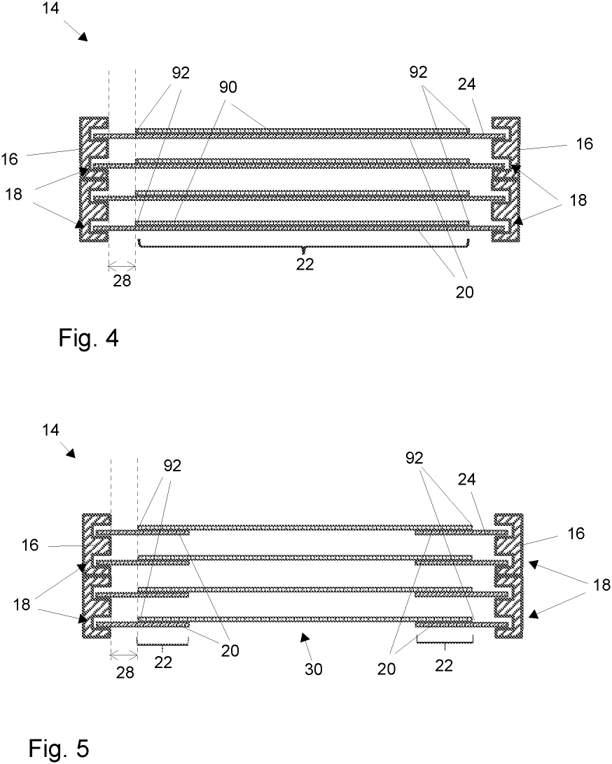

In the most general terms the present disclosure may provide a semiconductor substrate processing apparatus 10. An example of the semiconductor substrate processing apparatus 10 is shown in FIG. 1. The semiconductor substrate processing apparatus 10 may comprise a processing chamber 12, a wafer boat 14, and a plurality of wafer supports 20. Examples of the wafer boat 12 with wafer supports 20 and wafers 90 are shown in FIGS. 4 and 5. The processing chamber 12 may be configured for batch processing a plurality of wafers 90. The processing may include depositing a layer on each wafer 90 of the plurality of wafers 90. The wafer boat 14 may be configured to accommodate the plurality of wafers 90 and be receivable in the processing chamber 12. The wafer boat 14 may comprise at least two wafer boat posts 16. Each wafer boat post 16 may comprise a plurality of slots 18. Each wafer support 20 of the plurality of wafer supports 20 may comprise a support area 22 and a flange 24. The support area may be configured to support at least a circumferential edge 92 of a wafer 90 of the plurality of wafers 90. The flange 24 may circumferentially surround the support area 22. The flange 24 may be receivable in and be supported by the slots 18. The flange 24 may have a width to create a distance 28 between the circumferential edge 92 of the wafer 90 of the plurality of wafers 90 and the wafer boat posts 16 of the wafer boat 14. The distance may be such that the wafer boat posts 16 do substantially not influence a layer thickness of the layer which is deposited on the wafer 90 during processing of the wafer 90.

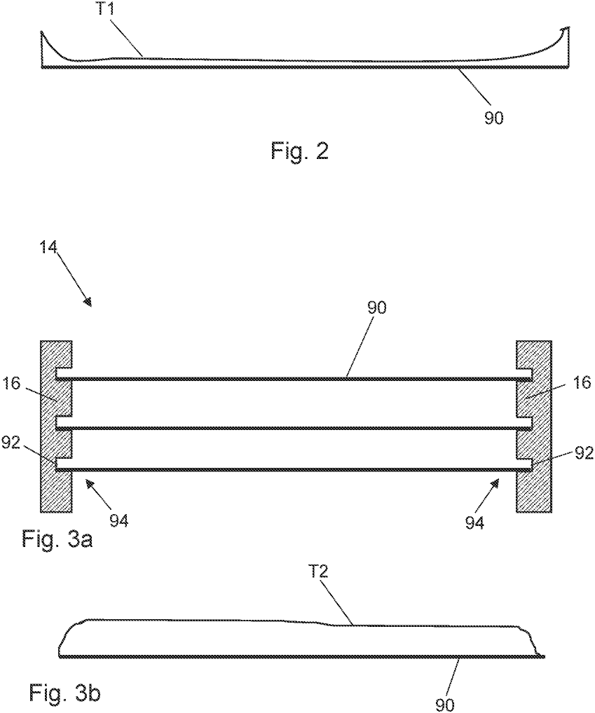

During deposition a precursor gas may be supplied in the processing chamber 12. This precursor gas may be deposited on the wafer 90 and form a layer of deposition material thereupon. The deposition of material on the wafer 90 may not always be uniform, which means that a layer thickness may vary. FIGS. 2 and 3b may show typical layer thickness profiles T1 and T2 over a wafer 90. The dimensions of the layer thicknesses shown in FIGS. 2 and 3b are not on the same scale as the diameter of the wafer 90 shown. FIG. 2 may show a typical layer thickness profile over a wafer 90 processed in a wafer boat 14 with no shield ring 62 present. The outer edge zone 94 may have been remote from the wafer boat posts 16 during processing. As is shown in FIG. 2, the edge effect may result in an accumulation of deposition material at or near the wafer edge 92 in the outer edge zone 94. FIG. 3b may show a typical layer thickness profile over a wafer 90 processed in a wafer boat 14, wherein the two outer edge zones 94 may have been adjacent the posts 16 of the wafer boat 14 in which the wafer 90 was placed when being processed, as may be seen in FIG. 3a. As is shown in FIG. 3b, the wafer posts 16 may cause that less material may be deposited on the wafer 90 near the wafer boat posts 16 resulting in a reduced layer thickness in an area adjacent the wafer boat posts relative the layer thickness in other areas of the wafer 90 which are more remote from the wafer boat posts 16. Combined these two effects may be superimposed and cause various kinds of deviations in the layer thickness in the edge zone 94 and adjacent the wafer boat posts 16.

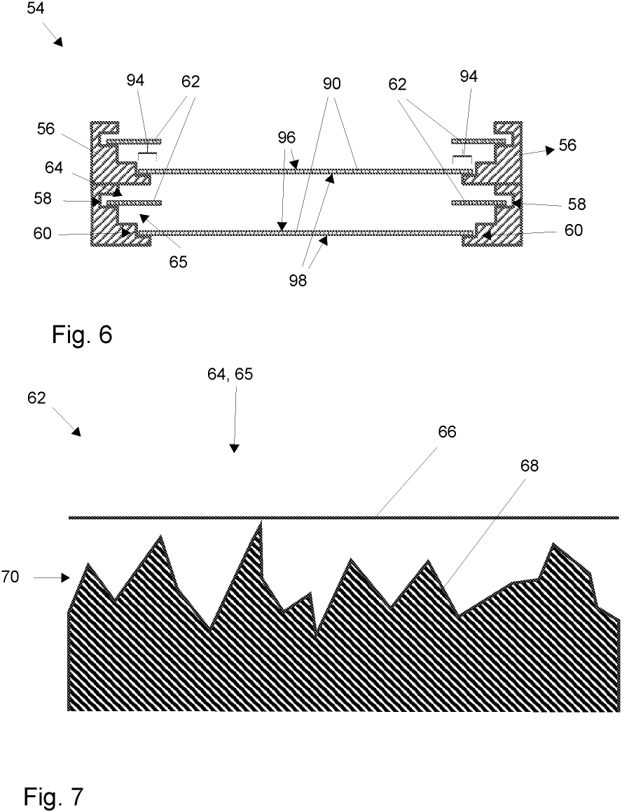

To counter the edge effect, the known semiconductor substrate processing apparatus may have a wafer boat with wafers and shield rings placed therein. The setup of this known wafer boat may be similar to the one shown in FIG. 6. But even in this set-up, the above described edge effect may not be solved in all processes and the above described effect of the wafer boat posts 16 on the layer thickness is not solved either.

In the semiconductor substrate processing apparatus 10 of the present disclosure, the flange 24 may create the distance 28 between the circumferential edge 92 of the wafer 90 and the wafer boat posts 16. This may result in a wafer boat 14 in which the wafer boat posts 16 are further away from the circumferential edge 92 of the wafer 90 than in the wafer boat of the known semiconductor substrate processing apparatus. The width may be chosen such that the thicker part of the deposited layer may be formed on the flange 24 of the wafer support 20 and not on the outer edge zone 92 of the wafer 90. Additionally, the above described undesired effects of the wafer boat posts 16 on the layer thickness of the deposited layer adjacent the wafer boat posts 16 may be reduced. This may lead to a more even distribution of deposited material on the wafer 90 itself, thereby improving the quality of the wafer 90.

As shown in FIG. 1, the semiconductor substrate processing apparatus 10 may comprise a wafer boat chamber 32 situated below the processing chamber 12. The wafer boat 14 may be configured to be transferred between the wafer boat chamber 32 and the processing chamber 12. The wafer boat chamber 32 may comprise a wafer handling robot 34, which may be configured to transfer wafers 90 to and from the wafer boat 14. An end effector 36 of the wafer handling robot 34 may be configured to engage the wafer 90.

In an embodiment the width of the flange 24 to create the distance between the circumferential edge 92 of the wafer 90 and the wafer boat posts 16 may be in the range between 5 and 35 mm, preferably between 10 and 25 mm, more preferably substantially 15 mm. This width of the flange 24 may suffice to reduce the influence of the wafer boat posts 16 on the layer thickness.

In an embodiment the distance 28 between the circumferential edge 92 of the wafer 90 and the wafer boat posts 16 may be in the range between 5 and 35 mm, preferably between 10 and 25 mm, more preferably substantially 10 mm. This distance between the wafer 90 and the wafer boat posts 16 may suffice to substantially reduce the influence of the wafer boat posts 16 on the layer thickness.

In an embodiment, of which an example is shown in FIG. 4, the support area 22 may be closed so that the wafer support 20 may be substantially plate-shaped and capable of supporting an entire bottom surface 98 of a wafer 90. The wafer support 20 may thus fully support the wafer 90 and may at the same time shield the bottom surface 98 from any deposited material. Especially in high process temperature applications, a fully supported wafer may be preferred to prevent bending of the wafer in the central region.

In an embodiment, of which an example is shown in FIG. 5, the support area 22 may comprise a central opening 30 so that the wafer support 20 may be substantially ring-shaped. Such a wafer support 20 may have less material and may thus be lighter and cheaper to manufacture than the plate-shaped wafer support 20 discussed above.

In an embodiment, the wafer support 20 with the wafer 90 may be removable from the wafer boat 14. An end effector 36 or the like, may be used to transport the wafer support 20. The end effector 36 may, for example, engage a bottom surface of the wafer support 20 and may carry the wafer support 20 together with the wafer 90.

In an embodiment the wafer support 20 may comprise quartz. Quartz may ensure that high purity is maintained while being able to withstand high temperature, while not reacting with the wafers 90 themselves or introducing particles which may cause impurities in the deposited layers..

In an embodiment the wafer support 20 may comprise silicon carbide (SiC). As quartz, silicon carbide may be a material with high temperature resistance.

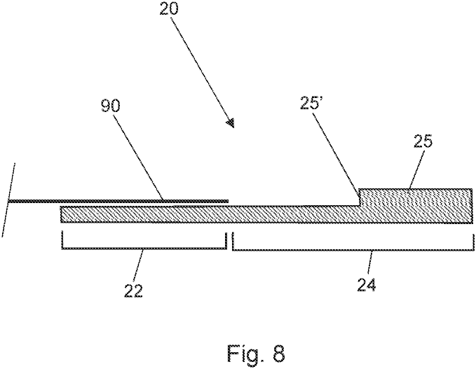

In an embodiment, of which an example is shown in FIG. 8, the wafer support 20 may comprise a thickened edge portion 25 which forms a wafer catching edge 25′. This wafer catching edge 25′ may prevent that a wafer 90 which is placed on the wafer support 20 may slip off the wafer support 20 during handling with the wafer handling robot 34. The thickened portion 25 may be integrally formed with the flange 24 of the wafer support 20 but may also be formed by a separate ring element which is connected on an upper surface of the wafer support 20.

The present disclosure may also provide another semiconductor substrate processing apparatus 10. The semiconductor substrate processing apparatus 50 may comprise a processing chamber 12, a wafer boat 54, and a shield ring 62. Examples of the wafer boat 54 of this example are shown in FIGS. 6 and 7. The processing chamber 12 may be configured for batch processing a plurality of wafers 90. The processing may include depositing a layer on each wafer 90 of the plurality of wafers 90. The wafer boat 54 may be configured to accommodate the plurality of wafers 90 and be receivable in the processing chamber 12. The wafer boat 54 may comprise at least two wafer boat posts 56. Each wafer boat post 56 may comprises a plurality of slots 58, 60. The shield ring 62 may be configured to be supported in the slots 58, 60 of the wafer boat posts 56 above an associated wafer 90. The shield ring 62 may shield a circumferential outer edge zone 94 at an upper surface 96 of the associated wafer 90. The circumferential outer edge zone 94 may be ring-shaped, having a radial width and extending circumferentially along a circumferential edge 92 of the wafer 90. A surface part 64, 65 of the shield ring 62 may define a nominal surface area 66 which is a surface area of the surface part 64, 65 if it were flat. The surface part 64, 65 may have a surface structure 70 which provides an enhanced surface area 68. An enhanced surface area ratio may be defined by the enhanced surface area 68 of the surface part 64, 65 having the surface structure 70 divided by the nominal surface area 66. The enhanced surface area ratio may be higher than 1.5.

A physical surface may have an enhanced surface area which may be different from the nominal surface area 66. An illustration hereof is shown in FIG. 7. The nominal surface area 66 may be a theoretical area which is completely flat. On a molecular scale every physical surface may have a topology or surface structure of the molecules or atoms which make up the material of which the surface is made. This topology or surface structure may determine the enhanced surface area 68. This may mean that for physical surfaces the enhanced surface area ratio is greater than one.

As with the previous semiconductor substrate processing apparatus 10, due to the edge effect the thickness of the deposited layer may be thicker in the outer edge zone 94 of the wafer 90 than in more central parts of the wafer 90. Although the known shield ring may shield the circumferential outer edge zone 94 at an upper surface 96 of the wafer 90, there still may be an accumulation of deposition material on said outer edge zone 94. With the shield ring 62 according to the description having a surface part 64 and/or 65 with an enhance surface area 68, such an accumulation of deposition material may be reduced.

With the surface part 64, 65 of the shield ring 62 which may have an enhanced surface area ratio of more than 1.5, more deposition material may be prevented from being deposited on the circumferential outer edge zone 94 of the wafer 90. This may even have as a result that no accumulation of deposition material on the circumferential outer edge zone 94 of the wafer 90 occurs and that a uniform layer thickness is obtained over at least the entire upper surface of the wafer 90.

Because of the high enhanced surface area ratio, the surface part 64 and/or 65 with the enhanced surface area 68 may have a relatively high roughness which may result in more deposition material adhering to the surface part 64 and/or 65 of the shield ring 62 according to the descripting thus reducing the edge effect.

Continuous use of the shield ring 62 during processing, may result in the deposition material smoothening the enhanced surface area. This may lead to the enhanced surface area ratio becoming smaller. To ensure the level of enhanced surface area ratio, it may be necessary to periodically treat the surface part 64, 65 of the shield ring 64 having the enhanced surface area ratio. The surface part 64 and/or, 65 of the shield ring 62 may e.g. be treated with an etching process to remove deposited material from the shield ring 62.

In an embodiment, the surface part of the shield ring 62 with the enhanced surface area 68 may exclusively comprise an upper surface 64 of the shield ring 62.

In an alternative embodiment, the surface part of the shield ring 62 with the enhanced surface area 68 may exclusively comprise a lower surface 65 of the shield ring 62.

In yet another alternative embodiment, the surface part of the shield ring 62 with the enhanced surface area 68 may comprise both an upper surface 64 and a lower surface 65 of the shield ring 62.

Which choice from these three embodiments is made depends on the type of deposition process and the materials used. It will be clear that the position of the enhanced surface area 68 on an upper surface 64, a lower surface 65 or on both may have an impact on the edge effect and thus on the layer thickness in the outer edge zone 94 of the wafer 90.

In an embodiment, the enhanced surface area ratio may be higher than 20, preferably higher than 50. This value of the enhance surface area ratio may be enough to prevent any accumulation of deposition material on the outer edge zone 94 of the wafer 90.

In an embodiment, the surface structure 70 may comprise a coating which provides a roughness. The coating may have a thickness between 500 nm to 5000 nm. Such a coating may provide the enhanced surface area 68 with the enhanced surface area ratio higher than 1.5, preferably higher than 20, and even more preferably higher than 50.

In an embodiment, the surface structure 70 may comprise a coating including hemi-spherical grains.

In an embodiment, the shield ring 62 may be manufactured from a construction material. The surface structure 70 may comprise geometrical shapes which are provided in the construction material to provide the enhanced surface area with the enhanced surface area ratio of the present disclosure. For example, the surface part 64, 65 of the shield ring 62 with the enhanced surface area 68 may be milled in a rough milling operation to provide the enhanced surface area.

In an embodiment, the surface part 64 and/or 65 with the enhanced surface area 68 may comprise a coating comprising silicon dioxide SiO₂.

In an embodiment, at least the surface part 64 and/or 65 of the shield ring 62 with the enhanced surface area 68 may comprise porous material. The porous material may comprise e.g. porous silicon oxide.

In an embodiment, the shield ring 92 may have a radial width which is selected such that the circumferential outer edge zone 94 which is shielded by the shield ring 92 may have a width in the range of 10 mm to 30 mm. This radial width may be enough to prevent the above-described edge effect.

In an embodiment, of which an example is shown in FIG. 5, the shield ring 62 may be at the same time a wafer support 20 comprising a support area 22 and a flange 24. The support area 22 may be configured to support at least a circumferential edge 92 of a wafer 90 of the plurality of wafers 90. The support area 22 may have a central opening 30 having a diameter which is smaller than a diameter of the wafer 90. The flange 24 may circumferentially surround the support area 22. The flange 24 may be receivable in and supported by the slots 18. The flange 24 may have a width to create a distance 28 between the circumferential edge 92 of the wafer 90 of the plurality of wafers 90 and the wafer boat posts 16 of the wafer boat 14. The distance 28 may be such that the wafer boat posts 16 do substantially not influence a layer thickness of the layer which is deposited on the wafer 90 during processing of the wafer 90.

As with the previous semiconductor substrate processing apparatus 10, the flange 24 may create the distance 28 between the circumferential edge 92 of the wafer 90 and the wafer boat posts 16. This may result in a wafer boat 14 in which the wafer boat posts 16 are further away from the circumferential edge 92 of the wafer 90 than in the wafer boat of the known semiconductor substrate processing apparatus. The width may be chosen such that the thicker part of the deposited layer caused by the edge effect may be formed on the flange 24 of the wafer support 20 and not on the outer edge zone 92 of the wafer 90. This may lead to a more even distribution of deposited material on the wafer 90 itself, thereby improving the quality of the wafer 90. The shield ring 62 for the associated wafer 90, which is at the same time the wafer support 20 for the wafer 90 directly above the associated wafer 90, not only reduces the edge effect due to the enhanced surface area of the shield ring 62 but also reduces the negative influence of wafer boat posts 56 on the uniformity of the layer thickness because the flange 24 of the wafer support 20/shield ring 62 provides an increased distance between the circumferential edge 92 of the wafer 90 and the wafer boat posts 56.

Again, in a further elaboration of this embodiment, of which an example is shown in FIG. 8, the wafer support 20 may comprise a thickened edge portion 25 which forms a wafer catching edge 25′. This wafer catching edge 25′ may prevent that a wafer 90 which is placed on the wafer support 20 may slip off the wafer support 20 during handling with the wafer handling robot 34. The thickened portion 25 may be integrally formed with the flange 24 of the wafer support but may also be formed by a separate ring element which is connected on an upper surface of the wafer support 20.

In an alternative embodiment, of which an example is shown in FIG. 6, the shield ring 62 may, according to the present disclosure, have a surface part 64 and/or 65 with an enhanced surface area and may be accommodated in between wafers 90 in the wafer boat 54 in shield ring slots 58 which are positioned between wafer slots 60 of wafer boat posts 56 which are configured to accommodate wafers 90 in the wafer boat 54.

In this way each wafer 90 may be shielded by the shield ring 62 directly positioned above said wafer 90. In this embodiment, the shield ring 62 does not have the function of wafer support 20.

An advantage of the embodiment of FIG. 5 with wafer supports 20 which also serve as shield rings 62 due to the enhanced surface area thereof is that more wafers 90 may be placed in a wafer boat 18 having a certain height. This is because the end effector 36 requires a certain distance between the subsequent objects to be placed in the wafer boat 16. When between each wafer 90 in a wafer boat 56 a shield ring 62 has to be placed by the end effector 36, as is the case in the example shown in FIG. 6, the distance between subsequent wafers 90 is inevitably larger (as is visible in when comparing FIG. 6 with FIG. 5) than in the situation in which the wafer support 20 also has the shield ring function (as in FIG. 5) due to its enhanced surface area with the enhanced surface area ratio of higher than 1.5.

Although illustrative embodiments of the present invention have been described above, in part with reference to the accompanying drawings, it is to be understood that the invention is not limited to these embodiments. Variations to the disclosed embodiments can be understood and effected by those skilled in the art in practicing the claimed invention, from a study of the drawings, the disclosure, and the appended claims.

Reference throughout this specification to “one embodiment” or “an embodiment” means that a particular feature, structure or characteristic described in connection with the embodiment is included in at least one embodiment of the present invention. Thus, the appearances of the phrases “in one embodiment” or “in an embodiment” in various places throughout this description are not necessarily all referring to the same embodiment.

Furthermore, it is noted that particular features, structures, or characteristics of one or more of the various embodiments which are described above may be used implemented independently from one another and may be combined in any suitable manner to form new, not explicitly described embodiments. The reference numbers used in the detailed description and the claims do not limit the description of the embodiments, nor do they limit the claims. The reference numbers are solely used to clarify.

### LEGEND

10 - semiconductor substrate processing apparatus
12 - processing chamber
14 - wafer boat
16 - wafer boat post
18 - slot
20 - wafer support
22 - support area
24 - flange
25 - thickened edge portion of wafer support
25′ - wafer catching edge
28 - distance between the circumferential edge of the wafer and the wafer boat posts
30 - central opening
32 - wafer boat chamber
34 - wafer handling robot
36 - end effector
54 - wafer boat
56 - wafer boat post
58 - shield ring slot
60 - wafer slot
62 - shield ring
64 - upper surface (of shield ring)
65 - lower surface (of shield ring)
66 - nominal surface area
68 - enhanced surface area
70 - surface structure
90 - wafer
92 - circumferential edge (of wafer)
94 - circumferential outer edge zone
96 - upper surface (of wafer)
98 - bottom surface (of wafer)
T1 - layer thickness at cross-section remote from wafer boat posts
T2 - layer thickness at cross-section comprising wafer boat posts

1. A semiconductor substrate processing apparatus, comprising:
a processing chamber configured for batch processing a plurality of wafers, wherein the processing includes depositing a layer on each wafer of the plurality of wafers;
a wafer boat configured to accommodate the plurality of wafers and receivable in the processing chamber, the wafer boat comprising at least two wafer boat posts, wherein each wafer boat post comprises a plurality of slots; and
a plurality of wafer supports, each wafer support of the plurality of wafer supports comprising:
a support area configured to support at least a circumferential edge of a wafer of the plurality of wafers; and
a flange circumferentially surrounding the support area, wherein the flange is receivable in and supported by the slots, wherein the flange has a width to create a distance between the circumferential edge of the wafer of the plurality of wafers and the wafer boat posts of the wafer boat, wherein the distance is such that the wafer boat posts do substantially not influence a layer thickness of the layer which is deposited on the wafer during processing of the wafer.

2. The semiconductor substrate processing apparatus according to claim 1, wherein the width of the flange to create the distance between the circumferential edge of the wafer and the wafer boat posts is in a range between 5 and 35 mm, preferably between 10 and 25 mm, more preferably substantially 15 mm.

3. The semiconductor substrate processing apparatus according to claim 1, wherein the distance between the circumferential edge of the wafer and the wafer boat posts is in a range between 5 and 35 mm, preferably between 10 and 25 mm, more preferably substantially 10 mm.

4. The semiconductor substrate processing apparatus according to claim 1, wherein the support area is closed so that the wafer support is substantially plate-shaped and capable of supporting an entire bottom surface of a wafer.

5. The semiconductor substrate processing apparatus according to claim 1, wherein the support area comprises a central opening so that the wafer support is substantially ring-shaped.

6. The semiconductor substrate processing apparatus according to claim 1, wherein the wafer support with the wafer is removable from the wafer boat.

7. The semiconductor substrate processing apparatus according to claim 1, wherein the wafer support comprises a thickened edge portion which forms a wafer catching edge (25′).

8. A semiconductor substrate processing apparatus, comprising:
a processing chamber configured for batch processing a plurality of wafers, wherein the processing includes depositing a layer on each wafer of the plurality of wafers;
a wafer boat configured to accommodate the plurality of wafers and receivable in the processing chamber, the wafer boat comprising at least two wafer boat posts, wherein each wafer boat post comprises a plurality of slots; and
a shield ring configured to be supported in the slots of the wafer boat posts above an associated wafer, the shield ring shielding a circumferential outer edge zone at an upper surface of the associated wafer, the circumferential outer edge zone being ring-shaped, having a radial width and extending circumferentially along a circumferential edge of the wafer,
wherein a surface part of the shield ring defines a nominal surface area which is a surface area of the surface part if it were flat, wherein the surface part has a surface structure which provides an enhanced surface area,
wherein an enhanced surface area ratio is defined by the enhanced surface area of the surface part having the surface structure divided by the nominal surface area, wherein the enhanced surface area ratio is higher than 1.5.

9. The semiconductor substrate processing apparatus according to claim 8, wherein the surface part of the shield ring with the enhanced surface area exclusively comprises an upper surface of the shield ring.

10. The semiconductor substrate processing apparatus according to claim 8, wherein the surface part of the shield ring with the enhanced surface area exclusively comprises a lower surface of the shield ring.

11. The semiconductor substrate processing apparatus according to claim 8, wherein the surface part of the shield ring with the enhanced surface area comprises both an upper surface and a lower surface of the shield ring.

12. The semiconductor substrate processing apparatus according to claim 8, wherein the surface structure comprises a coating which provides a roughness.

13. The semiconductor substrate processing apparatus according to claim 8, wherein the shield ring is manufactured from a construction material, wherein the surface structure comprises geometrical shapes which are provided in the construction material.

14. The semiconductor substrate processing apparatus according to claim 8, wherein the surface part with the enhanced surface area comprises a coating comprising silicon dioxide (Si02).

15. The semiconductor substrate processing apparatus according to claim 8, wherein at least the surface part with the enhanced surface area of the shield ring comprises porous material.

16. The semiconductor substrate processing apparatus according to claim 8, wherein the shield ring has a radial width which is chosen such that the circumferential outer edge zone which is shielded by the shield ring has a width in a range of 10 mm to 30 mm.

17. The semiconductor substrate processing apparatus according to claim 8, wherein the shield ring is a wafer support comprising:
a support area configured to support at least a circumferential edge of a wafer of the plurality of wafers, wherein the support area has a central opening having a diameter which is smaller than a diameter of the wafer; and
a flange circumferentially surrounding the support area, wherein the flange is receivable in and supported by the slots, wherein the flange has a width to create a distance between the circumferential edge of the wafer of the plurality of wafers and the wafer boat posts of the wafer boat, wherein the distance is such that the wafer boat posts do substantially not influence a layer thickness of the layer which is deposited on the wafer during processing of the wafer.

18. The semiconductor substrate processing apparatus according claim 17, wherein the wafer support comprises a thickened edge portion which forms a wafer catching edge.

19. The semiconductor substrate processing apparatus according to claim 8, wherein the shield ring is accommodated in between wafers in the wafer boat in shield ring slots which are positioned between wafer slots which are configured to accommodate wafers in the wafer boat.
